(19) United States
(12) Patent Application Publication
(10) Pub. No.: US 2019/0288505 A1
(43) Pub. Date: Sep. 19, 2019

(54) PROTECTION CIRCUIT

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hisami SAITO, Kitakyushu Fukuoka (JP)

(21) Appl. No.: 16/115,260

(22) Filed: Aug. 28, 2018

(30) Foreign Application Priority Data
Mar. 19, 2018 (JP) 2018-051189

(51) Int. Cl. H02H 9/04; H01L 27/02

(52) U.S. Cl. CPC H02H 9/046; H01L 27/0251

(57) ABSTRACT

A protection circuit that is provided inside a semiconductor package to protect a first transistor including a first collector connected to a terminal of the semiconductor package, a first emitter, and a first base. The protection circuit includes a second transistor that includes a second collector connected to the terminal, a grounded second emitter, and a second base; and a third transistor that includes a third collector connected to the terminal, a third emitter connected to the second base, and a third base. A breakdown voltage between the third collector and the third base is lower than a breakdown voltage between the first collector and the first base.

### CROSS-REFERENCE TO RELATED APPLICATION

This application is based upon and claims the benefit of priority from Japanese Patent Application No. 2018-051189, filed Mar. 19, 2018, the entire contents of which are incorporated herein by reference.

### FIELD

Embodiments described herein relate generally to a protection circuit.

### BACKGROUND

When static electricity accumulated on human bodies or external devices flows into semiconductor packages via input/output terminals due to any contact, circuits in the semiconductor packages may be broken down due to the static electricity. To prevent the breakdown, electro-static-discharge (ESD) protection circuits are provided near the input/output terminals of the semiconductor packages.

### DESCRIPTION OF THE DRAWINGS

FIG. 1 is a diagram illustrating an overall configuration of a semiconductor package including a protection circuit according to an embodiment;

FIGS. 2A and 2B are each a sectional view illustrating a structure of a transistor in the protection circuit of FIG. 1;

FIG. 3 is a diagram illustrating an operation of the protection circuit according to the embodiment;

FIG. 4 is a diagram illustrating an overall configuration of a semiconductor package including a protection circuit according to a modification example of the embodiment; and

FIG. 5 is a sectional view illustrating a structure of MOS transistors in the protection circuit of FIG. 4.

### DETAILED DESCRIPTION

Embodiments provide a protection circuit capable of improving operation reliability.

In general, according to one embodiment, a protection circuit that is provided inside a semiconductor package to protect a first transistor including a first collector connected to a terminal of the semiconductor package, a first emitter, and a first base. The protection circuit comprises: a second transistor that includes a second collector connected to the terminal, a grounded second emitter, and a second base; and a third transistor that includes a third collector connected to the terminal, a third emitter connected to the second base, and a third base. A breakdown voltage of the third transistor is lower than a breakdown voltage of the first transistor.

Hereinafter, a protection circuit and a semiconductor device according to an embodiment of the disclosure will be described with reference to the drawings.

In the embodiments illustrated herein, an ESD protection circuit is provided in a semiconductor package 1.

### 1. Overall Configuration

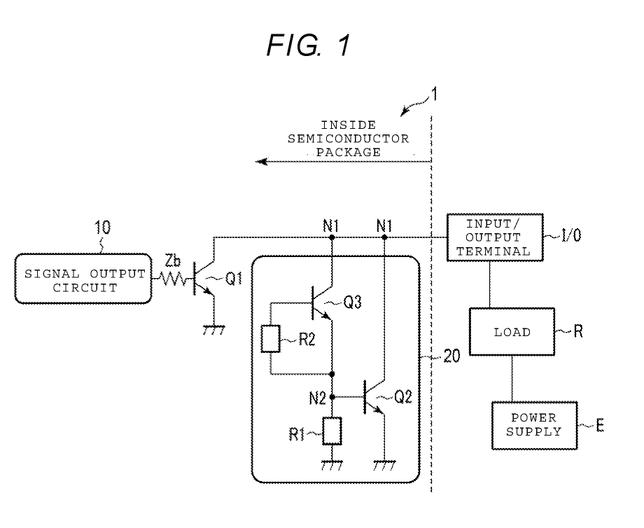

FIG. 1 is a diagram illustrating an overall configuration of the semiconductor package 1 according to an embodiment.

As illustrated, the semiconductor package 1 includes a bipolar transistor Q1, base impedance Zb, a signal output circuit 10, an ESD protection circuit 20, and an input/output terminal I/O.

The input/output terminal I/O is provided outside of the semiconductor package 1. Outside the semiconductor package 1, a load R and a power supply E are connected to the input/output terminal I/O.

The transistor Q1 includes an emitter (e.g., n-type), a base (e.g., p-type), and a collector (e.g., n-type).

The collector of the transistor Q1 is connected to the input/output terminal I/O via a node N1 and the emitter thereof is grounded. An output impedance of the signal output circuit 10 is connected to the base. The output impedance is represented by impedance Zb connected to the base of the transistor Q1 in the drawing and is referred to as base impedance Zb. An impedance value of the base impedance Zb is denoted by rb.

The signal output circuit 10 supplies a current Ib to the base of the transistor Q1 via the base impedance Zb according to a signal. The current Ib is amplified, a current (hereinafter, a collector current Ic1) flows to the collector of the transistor Q1 and a signal is output to the terminal.

Next, the ESD protection circuit 20 will be described. The ESD protection circuit 20 includes bipolar transistors Q2 and Q3 each including an emitter (e.g., n-type), a base (e.g., p-type), and a collector (e.g., n-type), a resistance element R1, and a resistance element R2.

The collector of the transistor Q2 is connected to the node N1, the base thereof is connected to a node N2, and the emitter thereof is grounded. A large collector current can flow via the transistor Q2. In particular, the transistor Q2 has an ability to sufficiently flow an ESD signal (i.e., current) caused due to static electricity applied to the input/output terminal I/O. As an example of the ability of the transistor Q2, the transistor Q2 may have a large size or may have a current amplification factor 3 of a value to the extent that the ESD signal can be sufficiently discharged.

Here, the resistance element R1 is provided between the base (i.e., node N2) and the emitter. A resistance value of the resistance element R1 is denoted by r1. The resistance value r1 is set to a resistance value in which the transistor Q2 is not turned on with a normally used voltage.

Next, the transistor Q3 will be described.

The size (for example, occupation area) of the transistor Q3 on the protection circuit board is reduced by 1/10 to 1/20 compared to the sizes of the transistor Q1 and the transistor Q2.

This is because the transistor Q3 may function as a trigger for turning on at least the transistor Q2. A current flowing in the transistor Q3 flows to the base of the transistor Q2 to be amplified, and thus the collector current of the transistor Q2 flows. Therefore, the collector current of the transistor Q3 may not be necessarily a large value like the collector current of the transistor Q2.

The collector of the transistor Q3 is connected to the node N1 and the emitter thereof is connected to the base of the transistor Q2 via the node N2. The resistance element R2 is provided between the emitter and the base of the transistor Q3. Here, a resistance value of the resistance element R2 is denoted by r2. The resistance value r2 is also set to a resistance value in which the transistor Q3 is not turned on with a normally used voltage.

The resistance value r2 is set to a value which is the same as or equal to or greater than the resistance value r1 of the resistance element R1. With a relation of r2≥rb set between the resistance value r2 and the impedance value rb of the base impedance Zb, the transistor Q3 is first turned on. Thus, it is easy to protect the transistor Q1.

A breakdown voltage between the collector and the base of the transistor Q3 is set to be lower than a breakdown voltage between the collector and the base of the transistor Q1. This is because it is necessary to advance a timing at which the transistor Q3 is turned on than a timing at which the transistor Q1 is turned on. In order to set the breakdown voltage between the collector and the base of the transistor Q3 to be lower than the breakdown voltage between the collector and the base of the transistor Q1, for example, when a distance l₁₂ is a distance between semiconductor layers functioning as the base and the collector in the structure of the transistor Q3, the distance l₁₂ is set to be narrower than a distance between semiconductor layers functioning as the base and the collector of the transistor Q1.

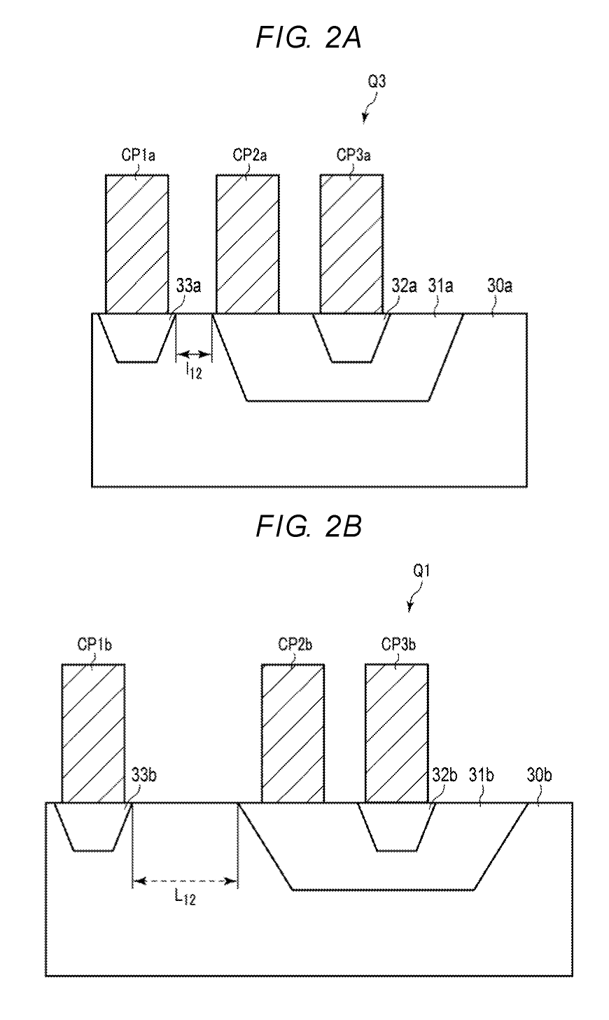

Specifically, the distance l₁₂ between the semiconductor layers functioning as the base and the collector of the transistor Q3 is set to be narrower than that of the transistor Q1 by 10% or more. A specific structure will be described later with reference to the following FIGS. 2A and 2B.

FIG. 2A is a sectional view illustrating the structure of the transistor Q3, and FIG. 2B is a sectional view illustrating the structure of the transistor Q1.

As illustrated in FIGS. 2A and 2B, the transistors Q3 and Q1 have structures in which an n-type semiconductor layer 30a (30b), a p-type semiconductor layer 31a (31b) functioning as a base and provided inside the n-type semiconductor layer 30a (30b), and an n-type semiconductor layer 32a (32b) functioning as an emitter and provided inside the p-type semiconductor layer 31a (31b) are formed in this order from the lower side and a p-type semiconductor layer 33a (33b) functioning as a collector and provided inside the n-type semiconductor layer 30a (30b) is formed.

In the structure of the transistor Q3 illustrated in FIG. 2A, a gap between the right end of the n-type semiconductor layer 33a and the left end of the p-type semiconductor layer 31a is “distance l₁₂”.

In the structure of the transistor Q1 illustrated in FIG. 2B, a gap between the right end of the n-type semiconductor layer 33b and the left end of the p-type semiconductor layer 31b is “distance L₁₂”.

As described above, the distance l₁₂ is narrower than the distance L₁₂ by 10% or more.

Because of a relation in which the breakdown voltage of the transistor is lowered when the distance is narrowed, as described above, by setting the distance l₁₂ to be lower than the distance L₁₂, the breakdown voltage of the transistor Q3 is lower than that of the transistor Q1 and an amount of charge leaking from the collector to the base at the time of applying a predetermined voltage is increased (hereinafter referred to as lowering the breakdown voltage).

By adopting this configuration, a relation of Ibc3>Ibc1 is established when the predetermined voltage is applied to the node N1.

Icb1 is a current leaking from the collector to the base in the transistor Q1, and Icb3 is a leakage current of the transistor Q3.

In this way, by lowering the breakdown voltage of the transistor Q3 with respect to the transistor Q1, a timing at which the transistor Q3 is turned on with a voltage applied to the collector side is advanced than in the transistor Q1.

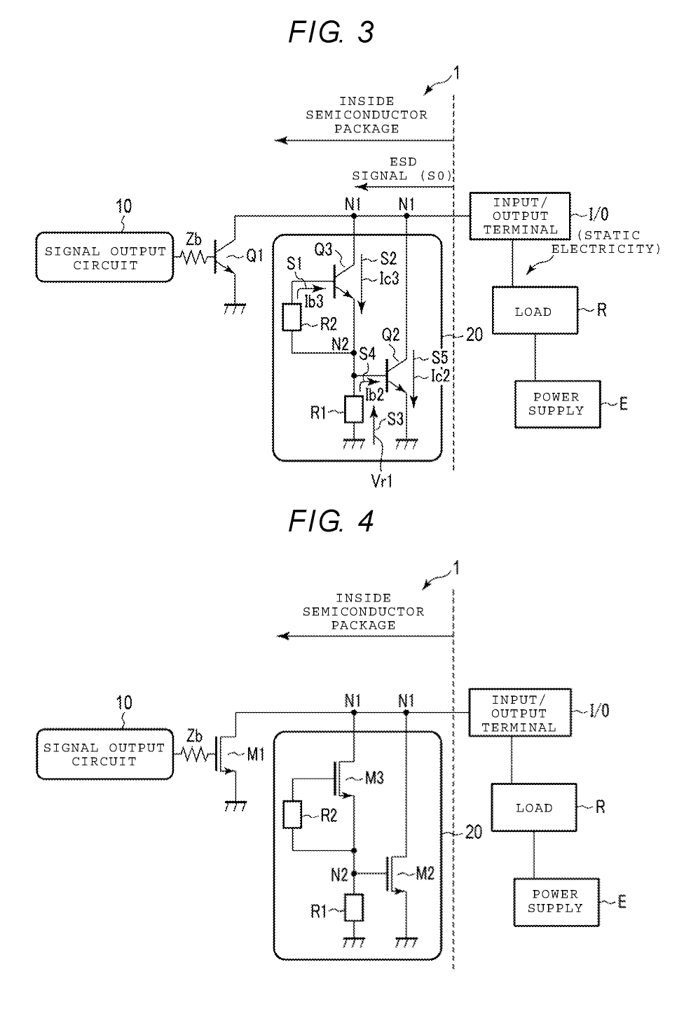

Next, an operation of the ESD protection circuit 20 provided inside the semiconductor package 1 will be described with reference to FIG. 3.

### 2. Operation

FIG. 3 is a diagram illustrating an operation performed by the ESD protection circuit 20 when the ESD signal invades into the semiconductor package 1 from an external device (not illustrated) via the input/output terminal I/O.

First, when static electricity generated outside propagates as the ESD signal in the load R or the like and invades inside the semiconductor package 1 via the input/output terminal I/O (step S0), a voltage according to the ESD signal is applied to the node N1. As a result, the potential of the collector of each of the transistors Q1 to Q3 increases.

Here, as described above, (1) the distance l₁₂ between the semiconductor layers in the collector and the base of the transistor Q3 is narrower than the distance L₁₂ between the semiconductor layers in the collector and the base of the transistor Q1, and thus the breakdown voltage of the transistor Q3 is lower than that of the transistor Q1. Therefore, in the transistor Q3, an amount of charge leaking from the collector to the base is greater than in the transistor Q1. Therefore, a base current Ib3 starts flowing earlier in the transistor Q3 than in the transistor Q1.

Since the transistor Q2 has a sufficiently large size so that a current necessary to protect the transistor Q1 can flow and the transistor Q2 is not broken down, its breakdown voltage is higher than the breakdown voltage in each of the transistor Q1 and the transistor Q3.

Accordingly, the base current Ib3 starts flowing to the transistor Q3 earlier than in the transistors Q1 and Q2 (step S1).

Then, a collector current Ic3 flows in the transistor Q3 to flow in the node N2 (step S2).

Subsequently, the transistor Q2 operates in the following way.

Specifically, when the collector current Ic3 in the transistor Q3 flows in the resistance element R1, a voltage Vr1 of Ic3×r1 is generated in the resistance element R1 (step S3).

The voltage Vr1 is applied to the base of the transistor Q2. Therefore, the base current Ib2 flows to the transistor Q2, and thus the transistor Q2 is turned on even when the voltage does not reach the breakdown voltage of the transistor Q2 (step S4). At this time, the transistor Q1 is not turned on, and thus the transistor Q2 is turned on earlier than the transistor Q1.

When the transistor Q2 is turned on, the ESD signal invading from the node N1 flows as a collector current Ic2 in the transistor Q2 (step S5).

As described above, the large collector current Ic2 can flow in the transistor Q2. Accordingly, the transistor Q2 can sufficiently discharge a large amount of ESD signal.

In this way, the ESD protection circuit 20 has a function of releasing the ESD signal along two current paths formed by the transistor Q2 in addition to the transistor Q3 by flowing the ESD signal invading from the node N1 as the collector current Ic2 to the transistor Q2.

### 3. Advantages According to Embodiments

The ESD protection circuit 20 according to the embodiment includes the transistor Q3 that has the configuration in which the breakdown voltage is lower than in the transistor Q1 and the transistor Q2 that is capable of sufficiently discharging the ESD signal.

Therefore, the ESD signal can be sufficiently discharged before the ESD signal invading inside the semiconductor package 1 via the input/output terminal I/O reaches the transistor Q1 which is a part of an internal circuit. Hereinafter, a more specific configuration will be described.

For example, in the structure of the transistor Q3, the distance l₁₂ between the semiconductor layers (33a and 31a) is set to be lower by, for example, 10% or more than the distance L₁₂ between the semiconductor layers (33b and 31b) in the structure of the transistor Q1. In this way, the transistor Q3 has a breakdown voltage lower than the transistor Q1. As a result, an amount of charge leaking from the collector to the base of the transistor Q3 is greater than that of the transistor Q1.

Accordingly, when the voltage according to the ESD signal is applied to the node N1, a voltage generated in the base of the transistor Q3 is higher than that of the transistor Q1 to the extent that a leakage amount of charge in the transistor Q3 is greater than that of the transistor Q1. Therefore, the base current Ib3 can flow in the transistor Q3 earlier than in the transistor Q1. As a result, the collector current Ic3 can flow to the transistor Q3 earlier than the collector current of the transistor Q1.

Further, in the ESD protection circuit 20 according to the embodiment, the resistance value r2 of the resistance element R2 disposed between the base and the emitter of the transistor Q3 is the same as or greater than the impedance value rb of the base impedance Zb.

Accordingly, the base current Ib3 flowing in the transistor Q3 flows in the resistance element R2, and thus a voltage Vb3 generated in the resistance element R2 can easily reach a value equal to or greater than a voltage generated in the base impedance Zb.

That is, even when a small amount of base current Ib3 flows in the transistor Q3, the voltage Vb3 generated in the resistance element R2 can easily increase and easily reach a value equal to or greater than a voltage generated in the base of the transistor Q1. Therefore, it is easy for the transistor Q3 to be turned on earlier. In particular, when the base currents and sizes of the transistors Q1 and Q3 are substantially the same, the transistor Q3 is turned on earlier than the transistor Q1. When the transistor Q3 is turned on, a current flows in the resistance element R1, a base voltage of the transistor Q2 increases, and the transistor Q2 is turned on. In this way, the transistor Q3 is turned on earlier than the transistor Q1, and thus the transistor Q2 is also turned on and the ESD signal can be discharged in conjunction with the large collector current Ic2 of the transistor Q2.

As a result, it is possible to form a path along which the ESD signal is discharged without invading the ESD signal into the transistor Q1.

Further, in the ESD protection circuit 20 according to the embodiment, the resistance value r2 of the resistance element R2 is set to be the same as or greater than the resistance value r1 of the resistance element R1.

Accordingly, the transistor Q3 can be easily turned on further earlier than the transistor Q2. As described above, since the breakdown voltage between the collector and the base in the transistor Q3 is less than in the transistor Q2, an amount of charge leaking from the collector to the base in the transistor Q3 is greater than in the transistor Q2. Accordingly, the transistor Q3 can be easily turned on earlier than the transistor Q2. In addition, the resistance value r2 of the resistance element R2 is set to be greater than the resistance value r1 of the resistance element R1. Thus, even when the amounts of charge leaking to the gates of the transistors Q3 and Q2 are the same, the transistor Q3 can be turned on earlier than the transistor Q2. In this way, it is possible to more reliably turn on the transistor Q3 earlier than the transistor Q2.

Further, in the ESD protection circuit 20 according to the embodiment, the size of the transistor Q3 is reduced by about 1/10 to 1/20 compared to the sizes of the transistors Q1 and Q2.

Accordingly, even in a case in which the transistor Q3 is added in addition to the transistor Q2, the transistor Q3 and furthermore the transistor Q2 can be turned on earlier than the transistor Q1 without expanding a circuit area since the size of the transistor Q3 is smaller. Therefore, the large amount of invading ESD signal can be discharged as the collector current Ic to the transistor Q2.

This is because even when the collector current Ic3 is a small value, because of the small size of the transistor Q3, it is possible to turn on the transistor Q2 that has the current amplification factor 3 of the large value to the extent that the ESD signal can be discharged, using the collector current Ic3.

For example, when the ESD protection circuit 20 includes only the transistor Q2 without providing the transistor Q3, the large amount of ESD signal has to be discharged as the collector current Ic2 from the transistor Q2. Therefore, the size of the transistor Q2 has to be large so that the amount of discharged current is tolerable.

However, as a result of the large size of the transistor Q2, the breakdown voltage may not be lowered in the transistor Q2 than in the transistor Q1 so that the transistor Q2 is turned on earlier than the transistor Q1. Therefore, the transistor Q1 may be turned on earlier than the transistor Q2, and thus the ESD signal may invade the transistor Q1.

In contrast, in the ESD protection circuit 20 according to the embodiment, the transistor Q3 can be driven earlier than the transistor Q1 and the transistor Q2 can be turned on. Therefore, it is possible to discharge the ESD signal as the collector current Ic2 in the transistor Q2 after the transistor Q3 while protecting the transistor Q1 against the ESD signal.

The transistor Q2 with a large size can also be considered to be turned on earlier than the transistor Q1 that has a smaller size than the transistor Q2 using another element, for example, a Zener diode, instead of providing the transistor Q3.

However, in this method, an ESD protection operation is not stable with a change in temperature due to temperature dependency of the Zener diode and a circuit area may be increased to form the Zener diode. The Zener diode may be unusable due to a manufacturing process.

In contrast, in the ESD protection circuit 20 according to the embodiment, the transistor Q2 can be turned on earlier than the transistor Q1 using the transistor Q3 with a smaller size. Accordingly, it is possible to discharge the ESD signal without a considerable increase in the circuit area.

As described above, it is possible to increase the ESD breakdown voltage of the semiconductor package 1.

### Modification Example

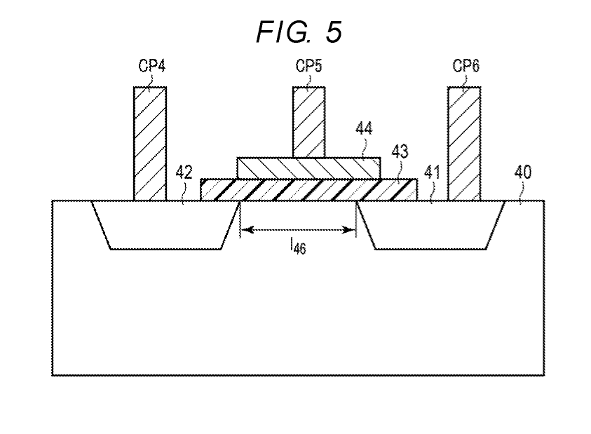

Next, a protection circuit according to a modification example of the foregoing embodiment will be described with reference to FIGS. 4 and 5. In the modification example, the bipolar transistors (Q1 to Q3) in the ESD protection circuit 20 according to the foregoing embodiment are configured with MOS transistors (M1 to M3), respectively. Here, breakdown voltages of the MOS transistors depend on distances (i.e., gate lengths) between semiconductor layers formed under the gates.

### 1. Circuit Configuration

FIG. 4 is a diagram illustrating an overall configuration of a semiconductor package 1 according to the modification example of the embodiment.

In the following description, the same reference numerals are given to the same configurations as those of the aforementioned embodiments and different configurations will be focused on.

As illustrated, the MOS transistors M1 to M3 are provided inside the semiconductor package 1.

In the MOS transistor M1, a drain is connected to the input/output terminal I/O via the node N1, a source is grounded, and an output impedance of the signal output circuit 10 is connected to a gate. In the MOS transistor M2, a drain is connected to the node N1, a gate is connected to the node N2, and a source is grounded. In the MOS transistor M3, a drain is connected to the node N1 and a source is connected to a base of the MOS transistor M2 via the node N2.

### 2. Sectional View

FIG. 5 is a sectional view illustrating a structure of the MOS transistors.

A p-type semiconductor layer 40 and n-type semiconductor layers 41 and 42 functioning as the drain and the source formed inside the p-type semiconductor layer 40 are formed from the lower side.

An oxide film 43 and a metal film (i.e., electrode) 44 are formed in sequence on the p-type semiconductor layer 40. The oxide film 43 and the metal film 44 form a gate oxide film and a gate electrode, respectively.

A contact plug CP4 is formed on the n-type semiconductor layer 42, a contact plug CP6 is formed on the n-type semiconductor layer 41, and a contact plug CP5 is formed on the metal film (i.e., electrode) 44.

Here, a distance (i.e., gate length) between the n-type semiconductor layer 41 and the n-type semiconductor layer 42 is denoted by l₄₆.

When the gate length l₄₆ of the MOS transistor illustrated in FIG. 5 is shortened, the breakdown voltage of the MOS transistor can be lowered. Thus, it is possible to obtain the advantage of narrowing the distance l₁₂ between the semiconductor layers (31a and 33a) in the above-described transistor Q3.

That is, when the MOS transistors corresponding to the transistors Q1 and Q3 are the MOS transistor M1 and the MOS transistor M3, the MOS transistor M3 can be turned on earlier than the MOS transistor M1 by shortening the gate length of the MOS transistor M3 further than the gate length of the MOS transistor M1.

Accordingly, it is possible to form a path along which the EDS signal is discharged without invading the ESD signal into the MOS transistor M1.

When the polarity of the ESD protection circuit according to the foregoing embodiment is reversed, the operation can be performed similarly by interchanging the n-type semiconductor and the p-type semiconductor of the transistors (Q1 to Q3) in the ESD protection circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A protection circuit that is provided inside a semiconductor package to protect a first transistor including a first collector connected to a terminal of the semiconductor package, a first emitter, and a first base,
the protection circuit comprising:
a second transistor that includes a second collector connected to the terminal, a grounded second emitter, and a second base; and
a third transistor that includes a third collector connected to the terminal, a third emitter connected to the second base, and a third base, wherein
a breakdown voltage between the third collector and the third base is lower than a breakdown voltage between the first collector and the first base.

2. The protection circuit according to claim 1, wherein
the first collector is formed by a first semiconductor layer of a first type;
the first base is formed by a second semiconductor layer of a second type that is provided inside the first semiconductor layer;
the third collector is formed by a third semiconductor layer of the first type;
the third base is formed by a fourth semiconductor layer of the second type that is provided inside the third semiconductor layer; and
a first distance between the third semiconductor layer and the fourth semiconductor layer is shorter than a second distance between the first semiconductor layer and the second semiconductor layer.

3. The protection circuit according to claim 2, wherein
the first distance is shorter than the second distance by 10% to 20%.

4. The protection circuit according to claim 2, wherein
the first and third semiconductor layers are of an n-type and the second and fourth semiconductor layers are of a p-type.

5. The protection circuit according to claim 2, wherein
the first and third semiconductor layers are of a p-type and the second and fourth semiconductor layers are of an n-type.

6. The protection circuit according to claim 1, further comprising:
a first resistor connected to the first base;
a second resistor provided between the second base and the second emitter; and
a third resistor that has a resistance value equal to or greater than a resistance value of the first resistor and that is provided between the third base and the third emitter.

7. The protection circuit according to claim 6, wherein
the resistance value of the third resistor is a value equal to or greater than a resistance value of the second resistor.

8. The protection circuit according to claim 6, wherein
a resistance value of the second resistor is a value equal to or greater than the resistance value of the first resistor.

9. The protection circuit according to claim 1, wherein
a current starts to flow in the third base before a current starts to flow in the first base, and
a current starts to flow in the second base after the third transistor is turned on and before the first transistor is turned on.

10. The protection circuit according to claim 1, wherein
an occupation area of the third transistor on the protection circuit is smaller by 10% to 20% compared to an occupation area of the first or the second transistor.

11. The protection circuit according to claim 1, wherein
each of the first, the second, and the third transistor is a bipolar transistor.

12. A semiconductor device comprising:
a terminal;
a first transistor that comprises a first collector connected to the terminal, a first emitter, and a first base;
a signal output circuit connected to the first base; and
a protection circuit that comprises:
a second transistor that includes a second collector connected to the terminal, a grounded second emitter, and a second base; and
a third transistor that includes a third collector connected to the terminal, a third emitter connected to the second base, and a third base, wherein
a breakdown voltage between the third collector and the third base is lower than a breakdown voltage between the first collector and the first base.

13. The semiconductor device according to claim 12, wherein
the first collector is formed by a first semiconductor layer of a first type;
the first base is formed by a second semiconductor layer of a second type that is provided inside the first semiconductor layer;
the third collector is formed by a third semiconductor layer of the first type;
the third base is formed by a fourth semiconductor layer of the second type that is provided inside the third semiconductor layer; and
a first distance between the third semiconductor layer and the fourth semiconductor layer is shorter than a second distance between the first semiconductor layer and the second semiconductor layer.

14. The semiconductor device according to claim 13, wherein
the first distance is shorter than the second distance by 10% to 20%.

15. The protection circuit according to claim 13, wherein
the first and third semiconductor layers are of an n-type and the second and fourth semiconductor layers are of a p-type.

16. The protection circuit according to claim 13, wherein
the first and third semiconductor layers are of a p-type and the second and fourth semiconductor layers are of an n-type.

17. The semiconductor device according to claim 12, further comprising:
a first resistor connected to the first base;
a second resistor provided between the second base and the second emitter; and
a third resistor that has a resistance value equal to or greater than a resistance value of the first resistor and that is provided between the third base and the third emitter.

18. The semiconductor device according to claim 17, wherein
the resistance value of the third resistor is a value equal to or greater than a resistance value of the second resistor.

19. The semiconductor device according to claim 17, wherein
a resistance value of the second resistor is a value equal to or greater than the resistance value of the first resistor.

20. A protection circuit that is provided inside a semiconductor package to protect a first MOS transistor including a first drain connected to a terminal of the semiconductor package, a first source, and a first gate,
the protection circuit comprising:
a second MOS transistor that includes a second drain connected to the terminal, a grounded second source, and a second gate;
a third MOS transistor that includes a third drain connected to the terminal, a third source connected to the second gate, and a third gate;
a first n-type semiconductor layer that functions as the first drain;
a second n-type semiconductor layer that functions as the first source;
a third n-type semiconductor layer that functions as the third drain; and
a fourth n-type semiconductor layer that functions as the third source, wherein
a distance between the third n-type semiconductor layer and the fourth n-type semiconductor layer is shorter than a distance between the first n-type semiconductor layer and the second n-type semiconductor layer.
